(19) United States
(12) Patent Application Publication
(10) Pub. No.: US 2013/0308667 A1
(43) Pub. Date: Nov. 21, 2013

(54) SEMICONDUCTOR LIGHT EMITTING DEVICE AND LIGHT EMITTING APPARATUS

(71) Applicant: PANASONIC CORPORATION, Osaka (JP)

(72) Inventors: Hiroyuki HAGINO, Osaka (JP); Katsuya SAMONJI, Kyoto (JP)

(73) Assignee: PANASONIC CORPORATION, Osaka (JP)

(21) Appl. No.: 13/951,455

(22) Filed: Jul. 25, 2013

Related U.S. Application Data
(63) Continuation of application No. PCT/JP2011/003840, filed on Jul. 5, 2011.

(30) Foreign Application Priority Data
Jan. 26, 2011 (JP) 2011-014032

(51) Int. Cl. H01S 5/024; H01S 5/22

(52) U.S. Cl. CPC H01S 5/024; H01S 5/22
USPC 372/36; 372/44.01

(57) ABSTRACT

A semiconductor light emitting device includes a nitride semiconductor layer, an insulating film, a first electrode, and a second electrode which are provided on a substrate. The nitride semiconductor layer includes a second cladding layer having a stripe-shaped ridge. The insulating film is provided on a portion of the second cladding layer including the at least one ridge. The first electrode is provided to contact the upper surface of the ridge. The second electrode is provided to contact the upper surface of the first electrode, the upper surface of the insulating film, and a portion of the second cladding layer exposed from the insulating film.

### CROSS-REFERENCE TO RELATED APPLICATIONS

This is a continuation of International Application No. PCT/JP2011/003840 filed on Jul. 5, 2011, which claims priority to Japanese Patent Application No. 2011-014032 filed on Jan. 26, 2011. The entire disclosures of these applications are incorporated by reference herein.

### BACKGROUND

The present disclosure relates to semiconductor light emitting devices and the light emitting apparatuses, and more particularly to semiconductor light emitting devices using nitride semiconductors and light emitting apparatuses.

Semiconductor light emitting devices emit light with high light output and with high directivity, and therefore, such devices have been actively developed as light sources of image display apparatuses such as laser displays and projectors, or light sources of industry processing equipment such as laser welding devices. In the field of image display apparatuses, laser devices and superluminescent diode (SLD) devices have been particularly developed, and in the field of industry processing equipment, laser devices and laser array devices have been particularly developed.

An indium aluminium gallium phosphide (InAlGaP) based material is used for semiconductor light emitting devices in which the emission wavelength ranges from red region (about 650 nm) to infrared region (about 1000 nm), and an indium aluminium gallium nitride (InAlGaN) based material is used for semiconductor light emitting devices in which the emission wavelength ranges from ultraviolet region (about 350 nm) to green region (about 530 nm).

In particular, it has been considered that the market for the semiconductor light emitting devices using the InAlGaP-based material would grow in the future as light sources for displays, and such devices have been actively developed. The semiconductor light emitting devices for use in such applications have been required to output light exceeding 1 W. In order to achieve semiconductor light emitting devices outputting light exceeding 1 W, it is necessary to improve the operating efficiency and the heat dissipation of the semiconductor light emitting devices. In order to reduce an increase in fabrication cost, the semiconductor light emitting devices have been also required to have a structure that can be easily manufactured.

A ridge structure in which stripe-shaped raised portions (ridges) are formed by removing a part of a cladding layer has been known as a structure that allows a semiconductor light emitting device such as a laser device to operate with high efficiency. In the ridge structure, in order to confine current and light, an insulating film whose refractive index is smaller than that of the cladding layer is formed so as to cover the cladding layer except the upper surface of the ridge. The insulating film covers the cladding layer, thereby making it possible not only to efficiently confine light to an optical waveguide, but also to confine current injected into an active layer. As a result, the luminous efficiency of the semiconductor light emitting device is improved to achieve the high-efficient operation of the semiconductor light emitting device.

In order to improve the heat dissipation of a semiconductor light emitting device, the semiconductor light emitting device has been generally connected to a heat sink. It has become the mainstream to form, on a substrate made of gallium nitride (GaN), the semiconductor light emitting device in which an InAlGaN-based material is used and an emission wavelength ranges from ultraviolet region to blue region. Since the thermal conductivity of the GaN substrate is 130 W/(m·K) which is higher than that of a GaAs substrate, heat dissipation via the substrate can be expected. Therefore, a junction-up mounting in which the GaN substrate and the heat sink are connected together has been generally used. In the junction-up mounting, heat generated in the active layer is mainly dissipated via the substrate located directly under the active layer. However, part of the heat generated in the active layer is conducted to a ridge side. The heat having been conducted to the ridge is conducted to an electrode formed on the ridge. Part of the heat having been conducted to the electrode is dissipated to the air, and part of the heat is conducted to a cladding layer. However, the efficiency of heat dissipation to the air is low. An insulating film is generally formed around the ridge, as described above. Silicon dioxide (SiO₂) that is a representative example of the insulating film has a low thermal conductivity of approximately 1.3 W/(m·K). Therefore, the heat conduction efficiency from the electrode to the cladding layer is low, and the heat is stored in the electrode. In a high-power semiconductor light emitting device outputting light of more than 1 Watt, electric power of several watts are supplied to a region of several hundred micrometers square, and therefore, improvement of the heat dissipation from a side closer to the ridge is an important problem to be solved.

In order to heat dissipation from the ridge, it has been considered to provide an uneven portion in a cladding layer except the ridge (for example, see Japanese Patent Publication No. 2006-173265). The uneven portion is provided to increase a surface area of the cladding layer, and therefore, improvement of the heat dissipation is expected.

It has also been considered to directly connect an electrode to a side surface of a ridge with no insulating film interposed therebetween (for example, see Japanese Patent Publication No. H03-156988). A contact electrode forming an ohmic contact with the ridge is formed on the upper surface of the ridge, and an interconnect electrode made of a metal forming a Schottky junction with the cladding layer is formed on the entire surface of the cladding layer including the upper surface of the contact electrode and the side surface of the ridge. The interconnect electrode has a thermal conductivity far larger than that of the insulating film, and therefore, the improvement of the heat dissipation from a side closer to the ridge can be expected.

### SUMMARY

However, the above conventional structures have the following problems. First, if an uneven portion is provided in the cladding layer, the heat dissipation cannot be significantly improved since the insulating film is formed between the electrode and the cladding layer. The fabrication process is complicated, causing an increase in fabrication cost.

When an interconnect electrode is directly formed on the cladding layer, the heat dissipation from the ridge can be improved. However, the interconnect electrode contacting the side surface of the ridge allows light absorption to occur, resulting in the reduction of the luminous efficiency. Furthermore, the ridge generally has a side surface that is almost perpendicular to the wafer surface, and a rising edge of the ridge is a large step. If the interconnect electrode is formed in the step, disconnection of the interconnect electrode is likely to occur. If the disconnection of interconnect electrode occurs, electric power is nonuniformly injected, and heat generation and light absorption increase, leading to a cause of deterioration of the device characteristics.

It is a problem of the present disclosure to solve the above problems, and to provide a semiconductor light emitting device which significantly improves the heat dissipation without reducing the luminous efficiency.

A semiconductor light emitting device of the present disclosure has a structure having: an insulating film covering a portion of a second cladding layer that includes a side surface of a ridge and exposing a portion of the second cladding layer; and a second electrode contacting the upper surface of a contact electrode, the upper surface of the insulating film, and the exposed portion of the second cladding layer from the insulating film.

Specifically, a first example semiconductor light emitting device includes: a nitride semiconductor layer including a first cladding layer, a light emitting layer, and a second cladding layer which are sequentially provided on a substrate, the second cladding layer including at least one ridge; an insulating film provided on a portion of the second cladding layer including the at least one ridge; a first electrode provided on the at least one ridge; and a second electrode provided to contact the first electrode, the insulating film, and a portion of the second cladding layer exposed from the insulating film, wherein the insulating film is provided on a side surface of the at least one ridge and a region adjoining the at least one ridge.

The first example semiconductor light emitting device includes the insulating film provided on a portion of the second cladding layer including the at least one ridge, and the second electrode formed to contact the first electrode, the insulating film, and a portion of the second cladding layer exposed from the insulating film. Therefore, in a portion in which the second electrode and the second cladding layer are directly connected together, heat can be efficiently conducted between the second electrode and the second cladding layer. Accordingly, when a junction-down mounting is performed, of the heat generated in the light emitting layer, the heat having been conducted to the side of the ridge can be efficiently conducted to a heat sink connected to a portion closer to the substrate, and the efficiency of heat dissipation can be improved. When a junction-up mounting is performed, the heat can be efficiently conducted to a heat sink connected to a portion closer to the electrode, and the efficiency of heat dissipation can be improved. The insulating film covers a region including a side surface of the ridge, and therefore, the light absorption around the ridge by the second electrode can be reduced, and the luminous efficiency can be improved.

In the first example semiconductor light emitting device, a width of a portion of the insulating film provided on the region adjoining the at least one ridge may be 1 μm or more and 10 μm or less, and may be preferably 1 μm or more and 2 μm or less.

In the first example semiconductor light emitting device, a nitrogen density of a portion of the second cladding layer around an interface with the second electrode may be smaller than a nitrogen density of an inside portion of the second cladding layer.

In the first example semiconductor light emitting device, the second electrode may be made of a material having a work function smaller than that of the first electrode.

In the first example semiconductor light emitting device, the second cladding layer may have a recessed/raised structure provided in a portion which is not covered with the insulating film.

In this case, the recessed/raised structure may be provided in a stripe pattern extending in parallel to the at least one ridge, and may be provided in a grid pattern.

In the first example semiconductor light emitting device, the at least one ridge includes a plurality of ridges, and the second cladding layer may have the plurality of ridges.

In the first example semiconductor light emitting device, the second cladding layer may include a plurality of layers having different compositions from each other or different materials from each other.

A second example semiconductor light emitting device includes: a nitride semiconductor layer including a first cladding layer, a light emitting layer, and a second cladding layer which are sequentially provided on a substrate; at least one ridge provided on the second cladding layer and including a first electrode made of a material which is transparent for an emission wavelength of light; an insulating film provided on a portion of the second cladding layer; and a second electrode provided to contact the at least one ridge, the insulating film, and a portion of the second cladding layer exposed from the insulating film, wherein the insulating film is provided on a side surface of the at least one ridge and a region adjoining the at least one ridge.

An example semiconductor light emitting apparatus includes: a heat sink; and the semiconductor light emitting device of the present disclosure mounted on the heat sink. The substrate of the semiconductor light emitting device may face the heat sink or the second cladding layer of the semiconductor light emitting device may face the heat sink.

The semiconductor light emitting device of the present disclosure can significantly improve heat dissipation without reducing luminous efficiency.

### BRIEF DESCRIPTION OF THE DRAWINGS

FIG. 1 is a cross-sectional view illustrating a semiconductor light emitting device according to an embodiment.

FIG. 2 is a cross-sectional view illustrating a fabrication process of the semiconductor light emitting device according to the embodiment.

FIG. 3 is a cross-sectional view illustrating a fabrication process of the semiconductor light emitting device according to the embodiment.

FIG. 4 is a cross-sectional view illustrating a fabrication process of the semiconductor light emitting device according to the embodiment.

FIG. 5 is a cross-sectional view illustrating a fabrication process of the semiconductor light emitting device according to the embodiment.

FIG. 6 is a cross-sectional view illustrating a fabrication process of the semiconductor light emitting device according to the embodiment.

FIGS. 7A and 8B illustrate an example of mounting the semiconductor light emitting device according to the embodiment, and FIG. 7A is a view from an emission side and FIG. 7B is a view from a transverse direction.

FIG. 8A is a cross-sectional view illustrating a heat dissipation path of a semiconductor light emitting device in which an insulating film is formed on the entire surface of the cladding layer, and FIG. 8B is a cross-sectional view illustrating a heat dissipation path of the semiconductor light emitting device according to the embodiment.

FIG. 9 is a graph showing a relationship between a light absorption and a width of a portion of the insulating film formed on a region adjoining a ridge.

FIG. 10 is a graph showing a relationship between a thermal resistance and the width of the portion of the insulating film formed on a region adjoining a ridge.

FIG. 11 is a graph showing a comparison of the current-light output characteristics between the semiconductor light emitting apparatus on which the semiconductor light emitting device according to the embodiment is mounted and a conventional semiconductor light emitting apparatus.

FIG. 12A is a cross-sectional view illustrating a ridge of a semiconductor device in which no insulating film is formed, and FIG. 12B is a cross-sectional view illustrating the ridge of the semiconductor device of the embodiment.

FIGS. 13A and 13B illustrate an example of mounting the semiconductor light emitting device according to the embodiment, and FIG. 13A is a view from an emission side and FIG. 13B is a view from a transverse direction.

FIG. 14 is a cross-sectional view illustrating a semiconductor light emitting device according to a first modification of the embodiment.

FIG. 15 is a plan view illustrating an example of the structure of recessed/raised portions of the semiconductor light emitting device according to the first modification of the embodiment.

FIG. 16 is a cross-sectional view illustrating a fabrication process of the semiconductor light emitting device according to the first modification of the embodiment.

FIG. 17 is a cross-sectional view illustrating a fabrication process of the semiconductor light emitting device according to the first modification of the embodiment.

FIG. 18 is a plan view illustrating another example of the structure of recessed/raised portions of the semiconductor light emitting device according to the first modification of the embodiment.

FIG. 19 is a cross-sectional view illustrating a semiconductor light emitting device according to a second modification of the embodiment.

FIG. 20 is a cross-sectional view illustrating a semiconductor light emitting device according to a third modification of the embodiment.

FIG. 21 is a cross-sectional view illustrating a semiconductor light emitting device according to a fourth modification of the embodiment.

FIG. 22 is a cross-sectional view illustrating another semiconductor light emitting device according to the fourth modification of the embodiment.

### DETAILED DESCRIPTION

### Embodiment

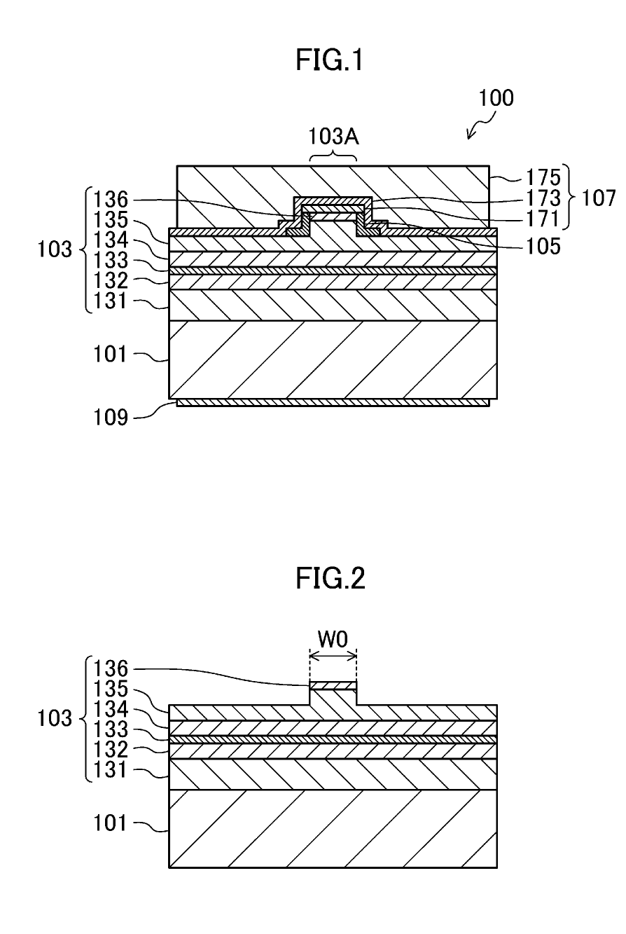

As illustrated in FIG. 1, a semiconductor light emitting device 100 is formed on a substrate 101, and includes a nitride semiconductor layer 103 having a stripe-shaped ridge 103A, an insulating film 105 covering the side surface of the ridge 103A and a predetermined region around the side surface of the ridge 103A, a p-side electrode 107 formed on the nitride semiconductor layer 103, and an n-side electrode 109 formed on a surface of the substrate 101 located on the opposite surface (back surface) from the nitride semiconductor layer 103.

The substrate 101 may be, e.g., n-type hexagonal GaN substrate having a (0001) principal surface. The nitride semiconductor layer 103 includes an n-type cladding layer 131, an n-type optical guide layer 132, a barrier layer (not shown), the active layer 133, a p-type optical guide layer 134, a carrier overflow suppression layer (OFS layer: not shown), a p-type cladding layer 135, and a p-type contact layer 136 which are sequentially formed from the substrate 101. The n-type cladding layer 131 may be, e.g., an n-type aluminum gallium nitride (AlGaN) layer having a thickness of 2 μm, and the n-type optical guide layer 132 may be, e.g., an n-type gallium nitride (GaN) layer having a thickness of 0.1 μm. The barrier layer may be, e.g., an indium gallium nitride (InGaN) layer. The active layer 133 may be, e.g., a quantum well active layer made of InGaN. The quantum well active layer may be formed of, e.g., a triple quantum well structure. The p-type optical guide layer 134 may be, e.g., a p-type GaN layer having a thickness of 0.1 μm. The OFS layer may be, e.g., an AlGaN layer having a thickness of 10 nm. The p-type cladding layer 135 may be, e.g., a strained superlattice layer having a thickness of 0.48 μm, and formed of a lamination of 160 cycles of p-type AlGaN layers each having a thickness of 1.5 nm and GaN layers each having a thickness of 1.5 nm. The p-type contact layer 136 may be, e.g., a p-type GaN layer having a thickness of 0.05 μm.

The nitride semiconductor layer 103 may be formed by, for example, a metal-organic chemical vapor deposition (MOCVD) technique. The ridge 103A may be formed by selectively removing the p-type contact layer 136 and the p-type cladding layer 135 after forming the nitride semiconductor layer 103, as illustrated in FIG. 2. The p-type contact layer 136 and the p-type cladding layer 135 may be selectively removed by inductively coupled plasma (ICP) etching using chlorine (Cl₂) gas. The p-type cladding layer 135 may be etched to a depth of about 400 nm. As a mask for the ICP etching, a silicon oxide film (SiO₂ film) having a thickness of 300 nm may be used, for example. When the mask is formed, a SiO₂ film is formed on the entire surface of the p-type contact layer 136 by, e.g., a thermal chemical vapor deposition (thermal CVD) technique using monosilane (SiH₄). Thereafter, the SiO₂ film is selectively removed by photolithography and reactive ion etching (RIE) using carbon tetrafluoride (CF₄) to have a stripe shape having a width of about 6 μm. After the formation of the ridge 103A, the mask of the SiO₂ film may be removed by wet-etching using hydrofluoric acid diluted with water (the ratio of the acid to the water is about 1 to 10).

A stripe width W0 of the ridge 103A will be now described. In general, in a ridge-type semiconductor laser device, light in a stripe width direction (transverse direction) is confined by a difference in effective refractive index between the ridge and the vicinity thereof. If the stripe width W0 is smaller than about 2 μm, a semiconductor laser device generally operates in a single-mode in which a horizontal transverse mode that is a transverse electric field distribution with respect to an active layer has a single-peak. If the stripe width W0 is about 2 μm or more, the semiconductor laser device operates in a multi-mode in which plural modes coexist. The stripe width W0 is extended to allow the semiconductor laser device to operate in the multi-mode, whereby the light density, the threshold carrier density, and the heat generation density in a light-emitting end facet can be reduced, and the output power can be increased, compared with the device in the single-mode. However, if the stripe width W0 is made too wide, the area of the ridge is increased, and as a result, an injected current is increased, heat is generated in the semiconductor laser device, and the semiconductor laser device cannot provide laser oscillation. The present inventors have studied the stripe width W0, and found that, if the stripe width W0 is 20 μm or less, the semiconductor laser device can provide laser oscillation. They also found that, if the stripe width W0 is 6-8 μm, the light output is maximum. Therefore, the stripe width W0 of the ridge 103A is preferably about 2 μm or more and about 20 μm or less, and more preferably about 6-8 μm. The condition in which the semiconductor device has the stripe width W0 of less than about 2 μm, and operates in the single-mode may be also utilized.

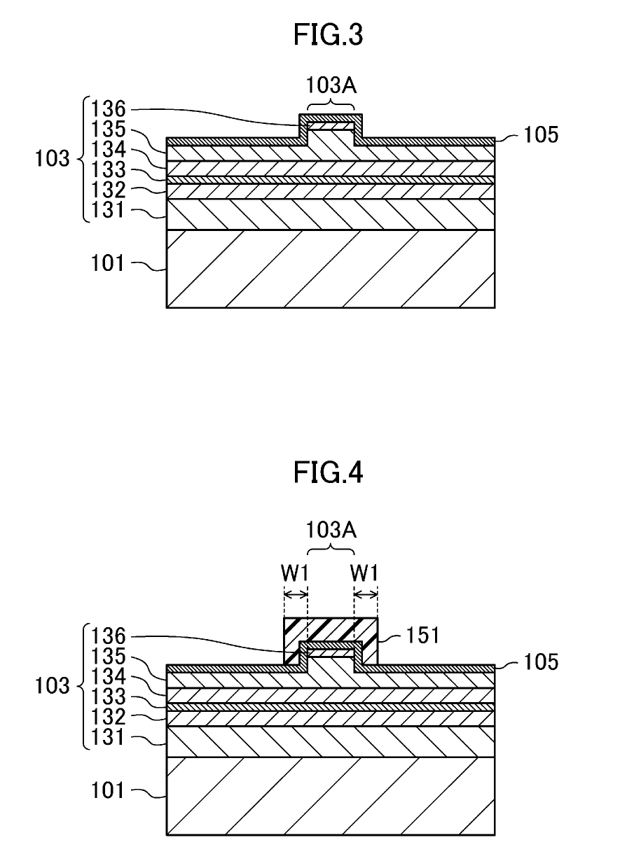

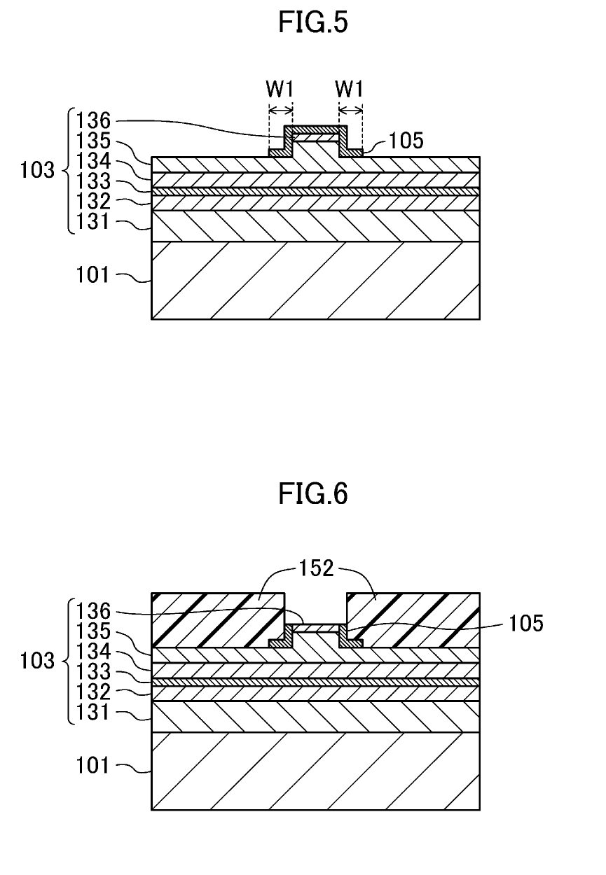

The insulating film 105 is formed on the surface of the ridge 103A and a region (of p-type cladding layer 135) adjoining the ridge 103A. The insulating film 105 serves a current confining layer confining current injected into the active layer 133. It also confines light to the optical waveguide. The insulating film 105 may be, e.g., a SiO₂ film having a thickness of about 300 nm. The insulating film 105 may be formed as follows, for example. As illustrated in FIG. 3, after the ridge 103A is formed in the nitride semiconductor layer 103, the insulating film 105 made of SiO₂ having a thickness of 300 nm is formed on the entire surface of the nitride semiconductor layer 103 to cover the ridge 103A. The insulating film 105 may be formed by, e.g., a thermal chemical vapor deposition (thermal CVD) technique using SiH₄. Next, as illustrated in FIG. 4, a resist mask 151 is formed by lithography to cover a predetermined region of the insulating film 105. The resist mask 151 is formed so as to cover the ridge 103A and a region located on the both sides of the ridge 103A having a width W1. Although the value of the width W1 can be selected optionally, a too long width W1 reduces the advantage of improving heat dissipation, and a too-short width W1 allows light absorption to occur. Next, as illustrated in FIG. 5, the exposed portion of the insulating film 105 is removed by, e.g., RIE using CF₄, and then, the resist mask 151 is removed by an organic solvent such as acetone. Next, as illustrated in FIG. 6, a resist mask 152 for exposing the upper surface of the ridge 103A is formed by photolithography, and the exposed portion of the insulating film 105 is removed by, e.g., RIE using CF₄ to expose the p-type contact layer 136.

The p-side electrode 107 includes a first electrode 171 serving as a contact electrode contacting the p-type contact layer 136, a second electrode 173 serving as an interconnect electrode, and a third electrode 175 serving as a pad electrode. The first electrode 171 forms an ohmic contact with the p-type contact layer 136, and may be a laminated film comprising palladium having a thickness of 50 nm and platinum having a thickness of 50 nm. The second electrode 173 contacts the first electrode 171, the insulating film 105, and a portion of the p-type cladding layer 135 that is not covered with the insulating film 105, and a width of the second electrode 173 in a direction intersecting the ridge 103A may be 150 μm, and a length of the second electrode 173 in a direction parallel to the ridge 103A may be 500 μm. The second electrode 173 may be a laminated film comprising, e.g., titanium having a thickness of 50 nm, platinum having a thickness of 200 nm, and gold having a thickness of 100 nm. The third electrode 175 may be gold having a thickness of 20 μm. The first electrode 171 and the second electrode 173 may be formed by, e.g., electron beam deposition and lift-off, and the third electrode 175 may be formed by, e.g., electroplating. In order to allow the first electrode 171 to form an ohmic contact, the first electrode 171 may be sintered at the temperature of, e.g., 400° C.

The n-side electrode 109 may be a laminated film comprising, e.g., titanium having a thickness of 5 nm, platinum having a thickness of 10 nm, gold having a thickness of 100 nm. The back surface of the substrate 101 may be polished with, e.g., diamond slurry, to reduce the thickness of the substrate 101 to about 80 μm, and then, the n-side electrode 109 may be formed by, e.g., electron beam deposition.

After such a structure is formed on the wafer, the wafer is cleaved into chips such that a width of each of the chips in a direction intersecting the ridge 103A is, e.g., 200 μm and a length of each of the chips in a direction parallel to the ridge 103A is, e.g., 800 μm to form the semiconductor light emitting device 100.

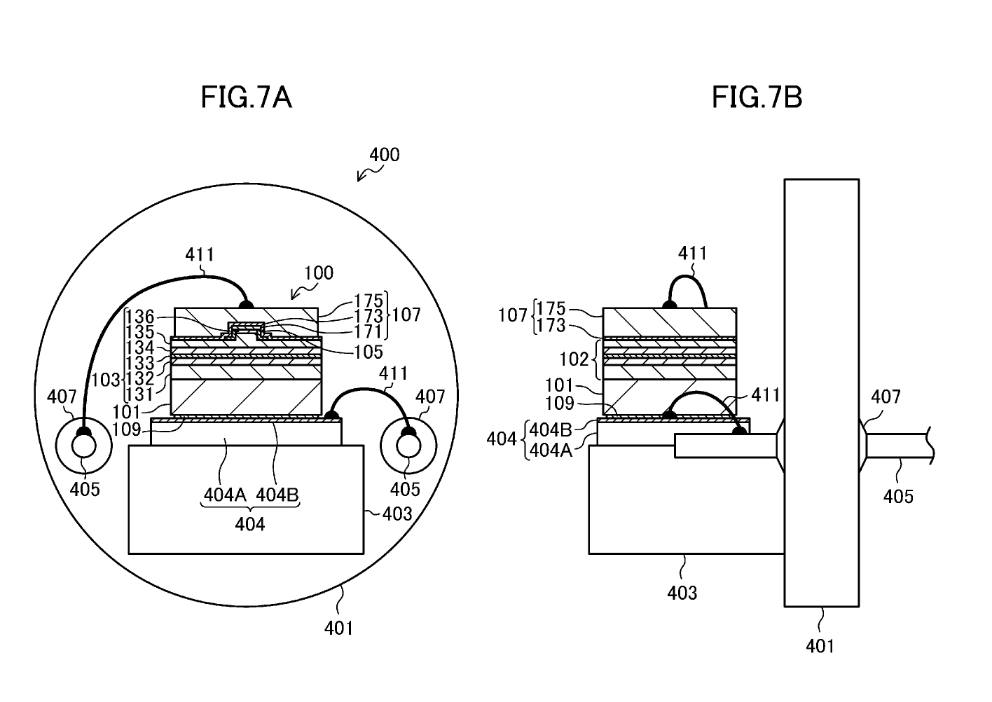

Next, a semiconductor light emitting apparatus on which the semiconductor light emitting device 100 of the embodiment is mounted will be described. FIGS. 7A and 7B illustrate an example of the semiconductor light emitting apparatus on which the semiconductor light emitting device 100 of the embodiment is mounted. The semiconductor light emitting device 100 is mounted on a package 400. The package 400 includes a base 401 serving as a support base supporting the light emitting device, a heat sink 403 fixed onto a face of the base 401, a sub-mount 404 fixed onto the heat sink 403, and two leads 405 fixed to the base 401 with an insulator 407 interposed therebetween in a through hole passing through the base 401. The sub-mount 404 has a sub-mount substrate 404A, and a sub-mount electrode 404 B provided on a face of the sub-mount substrate 404A. The sub-mount electrode 404B is connected to the n-side electrode 109 of the semiconductor light emitting device 100. One of the two leads 405 is connected to the sub-mount the substrate 404A through a wire 411, and the other of the two leads 405 is connected to the p-side electrode 107 of the semiconductor light emitting device 100 through another wire 411.

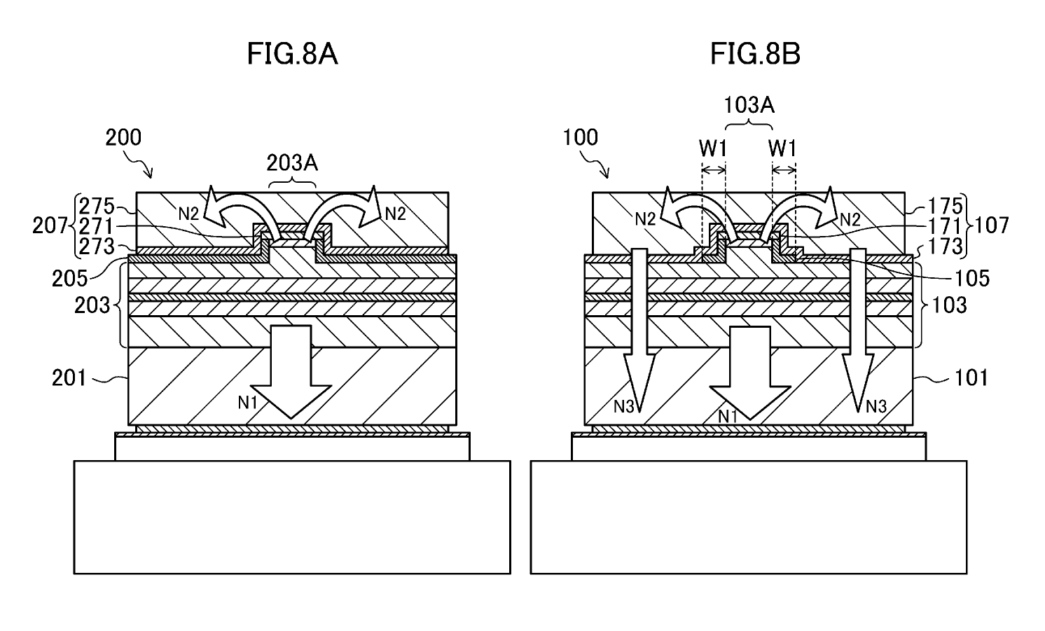

The efficiency of heat dissipation of the semiconductor light emitting device of the embodiment can be improved for the following reasons. As illustrated in FIG. 8A, in the case of a conventional semiconductor light emitting device 200 in which an insulating film 205 is fully provided between a second electrode 273 and a nitride semiconductor layer 203, the heat generated in a portion of an active layer located directly under the ridge 203A is conducted through a path N1 to the substrate 201. The heat is also conducted through a path N2 to the ridge 203A, and to a p-side electrode 207 formed by laminating a first electrode 271, the second electrode 273, and a third electrode 275. Part of the heat having been conducted to the p-side electrode 207 is dissipated from the third electrode 275 to the air. However, the efficiency of heat dissipation to the air is not high. The insulating film 205 having a low thermal conductivity is fully provided between a second electrode 273 and the nitride semiconductor layer 203, and therefore, the heat is less likely to be conducted from the second electrode 273 to the nitride semiconductor layer 203. Therefore, most heat having been conducted to the p-side electrode 207 through the path N2 is stored in the p-side electrode 207. Therefore, even if the substrate 201 is connected to the heat sink, the heat having been conducted to the ridge 203A cannot be efficiently dissipated.

In contrast, as illustrated in FIG. 8B, in the case of the semiconductor light emitting device 100 of the embodiment, the second electrode 173 and the nitride semiconductor layer 103 are directly connected together except a portion of both sides of the ridge 103A. The thermal conductivity of the second electrode 173 made of a metal is higher by about two digits than that of the insulating film 105 made of a SiO₂ film. Therefore, the heat having been conducted, through the path N2, to the p-side electrode 107 in which the first electrode 171, the second electrode 173, and the third electrode 175 are laminated is efficiently conducted to the nitride semiconductor layer 103 through the path N3, and is further conducted to the substrate 101. The heat sink is connected to the side closer to the substrate 101, thereby making it possible to efficiently dissipate not only the heat directly having been conducted from the active layer to the substrate 101 but also the heat once having been conducted to the ridge 103A.

The p-side electrode 107 may have a large thickness to sufficiently obtain the advantage by the heat dissipation paths N2 and N3. In the embodiment, since the third electrode 175 has a thickness of about 20 μm, the efficiency of the heat dissipation path N2 and N3 can be improved.

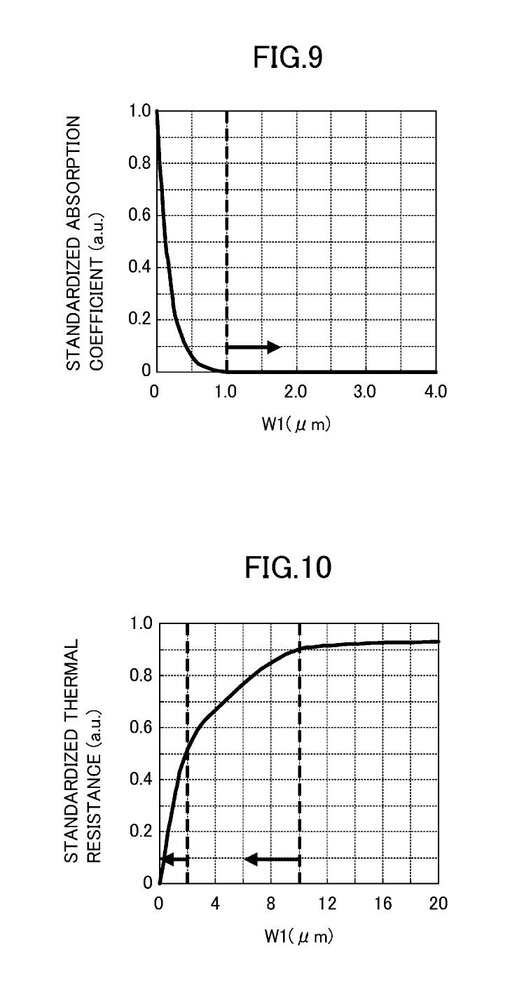

The luminous efficiency in the semiconductor light emitting device 100 of the embodiment can be sufficiently secured for the following reasons. FIG. 9 shows a result of a light absorption obtained by calculation when the width W1 of a region adjoining the ridge 103A and covered with the insulating film 105 is changed. The vertical axis represents a standardized absorption coefficient that is standardized such that, when the width W1 is 0 μm, the value of the coefficient is 1, and when the width W1 is 100 μm, the value of the coefficient is 0. As shown in FIG. 9, if the width W1 is smaller than 1 μm, the second electrode 173 formed in the sides of the ridge 103A absorbs light. However, if the width W1 is 1 μm or more, the second electrode 173 hardly absorbs light. That is because light intensity is quite small in a region located far from the side surface of the ridge 103A by 1 μm or more.

FIG. 10 shows a result of a thermal resistance obtained by calculation when the width W1 is changed. The vertical axis represents a standardized thermal resistance that is standardized such that, when the width W1 is 0 μm, the value of the resistance is 0, and when the width W1 is 100 μm, the value of the resistance is 1. As shown in FIG. 10, the smaller the width W1 is, the smaller the thermal resistance is. On the other hand, the smaller the width W1 is, the larger the rate of change (reduction rate) of the thermal resistance is. For example, if the width W1 is more than 10 μm, the reduction rate of the standardized thermal resistance is about 0.001 (μm⁻¹), and if the width W1 is in the range of 2-10 μm, the reduction rate of the standardized thermal resistance is about 0.04 (μm⁻¹), and if the width W1 is in the range of 0-2 μm, the reduction rate of the standardized thermal resistance is about 0.25 (μm⁻¹). In this way, the thermal resistance can be reduced if the width W1 is made smaller so that the second electrode 173 and the p-type cladding layer 135 are directly in contact with each other in a portion closer to the side surface of the ridge 103A. If the width W1 is smaller, the reduction rate of the thermal resistance is larger, and therefore, if the width W1 can be made slightly smaller, the thermal resistance can be greatly reduced. That is because the heat is generated in the ridge 103A and is dispersed therefrom, and therefore, a smaller thermal conductivity in a portion near a heat source improves the efficiency of heat dissipation.

In view of the above, in order that light absorption can be ignored while the heat dissipation is secured, the width W1 of the region covered with insulating film 105 may be in the range of about 1-10 μm, and more preferably in the range of about 1-2 μm. In the embodiment, if the width W1 is 1 μm, the light absorption can be almost ignored, and the heat dissipation can be maximized.

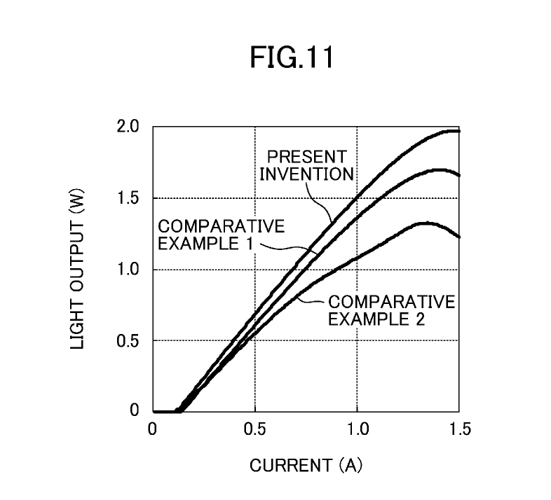

FIG. 11 shows an example of the current-light output characteristics in the semiconductor light emitting apparatus on which the semiconductor light emitting device 100 of the embodiment is mounted by a junction-up method. As shown in FIG. 11, in the case of a comparative example 1 in which an insulating film for current confinement covers the entire surface of a p-type cladding layer, and the p-type cladding layer and an interconnect electrode are not directly connected together, the light output is saturated at about 1.7 W due to the thermal effect. In contrast, the maximum light output of the semiconductor light emitting apparatus of the embodiment is about 2 W, which is about 1.2 times larger than that of the comparative example 1. That is because the heat is efficiently conducted form the interconnect electrode to the p-type cladding layer, and the efficiency of the heat dissipation of the semiconductor light emitting apparatus is improved. In the case of a comparative example 2 in which no insulating film is formed between an interconnect electrode and a p-type cladding layer, the light output is saturated at about 1.3 W, and the slope efficiency referring to the slope of the current-light output characteristics is low, compared with that of the semiconductor light emitting apparatus of the embodiment and that of the comparative example 1. In the case of the comparative example 2 in which the p-type cladding layer and the interconnect electrode are directly connected together, the light emission characteristics of the device are obviously deteriorated greater than that of the light emitting device of the embodiment. That is because of the effect of light absorption caused by a direct contact between the interconnect electrode and the side surface of the ridge.

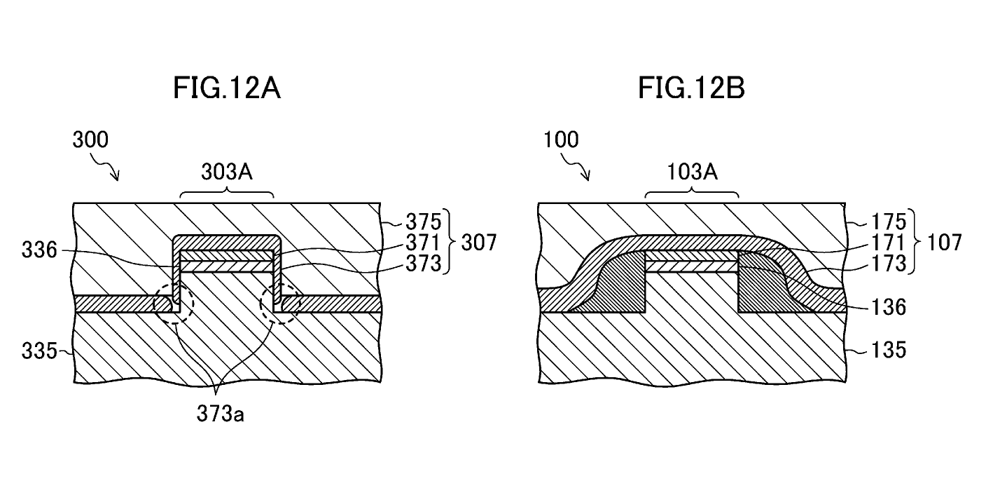

Next, the semiconductor light emitting device 100 of the embodiment can improve the disconnection of the electrode for the following reasons. FIG. 12A shows a semiconductor light emitting device 300 in which a first electrode 371 serving as a contact electrode, a second electrode 373 serving as an interconnect electrode, and a third electrode 375 serving as a pad electrode are directly formed on a ridge 303A. As illustrated in FIG. 12A, the side surface of the ridge 303A is substantially perpendicular to a wafer surface. The height of the ridge 303A including the p-type cladding layer 335 and the p-type contact layer 336 is approximately 450 nm, and a large step is generated. Therefore, in the semiconductor light emitting device 300 in which the second electrode 373 and the third electrode 375 serving as a pad electrode are directly formed with no insulating film interposed therebetween, a disconnection portion 373a is likely to occur in the second electrode 373. When the present inventors have actually produced a plurality of the structures of the embodiment on one wafer for evaluation, they found that a disconnection of the electrode occurs in the plurality of the device.

In contrast, in the semiconductor light emitting device 100 of the embodiment, the insulating film 105 is provided on a portion of the upper surface of the p-type cladding layer 135 which includes the side surface of the ridge 103A and a region adjoining the side surface of the ridge 103A, as illustrated in FIG. 12B. The insulating film 105 is deposited so that a flat portion of the insulating film 105 has a thickness of about 300 nm. The edge of the insulating film 105 is etched when the insulating film 105 is patterned. Therefore, as illustrated in FIG. 12B, the insulating film 105 can gently cover the side surface of the ridge 103A. Therefore, it is unnecessary to form the second electrode 173 in the large step, and the occurrence of the disconnection is reduced or prevented.

The semiconductor light emitting device 100 of the embodiment includes a portion in which the second electrode 173 and the p-type cladding layer 135 are directly connected together. Therefore, leakage current may flow from the second electrode 173 into the p-type cladding layer 135. However, the work function of p-type GaN is higher than that of a metal, generally used as an electrode material, such as nickel, palladium, titanium, gold, platinum, copper, aluminum, tantalum, tungsten, and chromium, and therefore, it is difficult to provide an ohmic contact between the p-side electrode and the p-type cladding layer. Therefore, a heavily doped contact layer made of p-type GaN is formed to have a thin thickness, and is sintered to alloy the p-side electrode. Such a structure can allow the carrier to tunnel a potential barrier to reduce the resistive connection of the p-side electrode. In the semiconductor light emitting device 100 of the embodiment, no heavily doped layer exists at a connection interface between the second electrode 173 and the p-type cladding layer 135. Therefore, the second electrode 173 and the p-type cladding layer 135 forms a Schottky junction, and current hardly flows between the second electrode 173 and the p-type cladding layer 135. If only the first electrode 171 is alloyed, it may be sintered after the formation of the first electrode 171 and before the formation of the second electrode 173.

In general, the bonding of nitrogen to other atoms is weaker than that of gallium, and therefore, nitrogen is likely to be removed from a semiconductor crystal. If the ridge of the p-type cladding layer 135 is formed by dry etching, the surface of the p-type cladding layer 135 is modified due to the dry etching, and a N hole from which nitrogen is removed. As a result, the etched surface is a low-nitrogen layer from which many nitrogen atoms are removed and which has a nitrogen density lower than that of the non-etched portion. The nitrogen density of a portion of the p-type cladding layer 135 around a connection interface with the second electrode 173 is smaller than that of the inside portion of the p-type cladding layer 135. If the N hole serves a donor, and the concentration of the N hole is substantially the same as the acceptor concentration of the p-type cladding layer 135, an inactive layer is formed. The inactive layer serves as a high-resistance layer, and current leakage can be reduced. If the concentration of the N hole is higher than the acceptor concentration of the p-type cladding layer 135, an n-type conversion layer is formed. If the n-type conversion layer is formed between the second electrode 173 and the p-type cladding layer 135, it serves as an npn junction and can prevent the occurrence of current leakage. In the embodiment, the p-type cladding layer 135 is dry etched, thereby simultaneously forming the ridge and the N hole, and heat dissipation can be improved without an increase in fabrication cost.

The modification of the surface increases with increasing the etching power. However, too large power causes a problem where controllability of the ridge shape and the etching depth is deteriorated. The present inventors found that the power that can both cause modification of the surface and maintain the controllability is about 100-200 W. If the p-type cladding layer 135 is heavily etched and the etched surface reaches the n-type cladding layer, current leakage occurs. As a result of the study of the present inventors, if the thickness of the p-type cladding layer 135 is 10 nm or more after etching, leakage current can be sufficiently controlled.

In order to further cause modification of the surface, for example, ion irradiation, plasma treatment, electron beam irradiation, and wet etching by phosphoric acid solution and alkaline solution may be performed after dry etching. A metal electrode that reacts to N may be in contact with the surface. For example, a metal electrode such as titanium (Ti) or vanadium (V) is in contact with the p-type cladding layer 135, whereby such a metal material is bonded to N on the surface to form, e.g., TiN or VN, and therefore, the N hole can be formed on the surface of the p-type cladding layer 135.

In order to form a high-resistance layer, for example, ion implantation or annealing may be performed. An ion such as iron, zinc, or boron is implanted into the p-type cladding layer 135, whereby an inactive region can be formed to increase the resistance of the surface of the p-type cladding layer 135. The modified surface of the p-type cladding layer 135 is likely to be oxidized, and therefore, the surface is annealed in an oxygen atmosphere, whereby the surface can be oxidized. The present inventors found that the annealing at a temperature in the range of 400-1000° C. can form a high-resistance layer that reduces current leakage. The oxidation reaction proceeds according to the crystal defect density. Therefore, after the process of damaging the surface is performed as described above, the surface is oxidized, thereby facilitating the oxidation reaction. In the embodiment, after the first electrode 171 is formed, sintering is performed in an oxygen atmosphere, thereby making it possible to form a contact junction in the first electrode 17 while oxidizing the etched surface. Such a process can reduce leakage current without increasing a fabrication cost.

In order to reduce leakage current between the second electrode 173 and the p-type cladding layer 135, it is preferable to use, as the second electrode, an electrode material having a work function that is as small as possible. In order to supply current to only the ridge 103A, it is preferable to use, as the first electrode 171, a material having a work function larger than that of the second electrode 173. For example, the combination of palladium and titanium, the combination of nickel and titanium, the combination of nickel and chromium, and the combination of nickel and aluminum are preferably used as the combination of the first electrode 171 and the second electrode 173. Each of the first electrode and the second electrode may be a laminated film formed by a plural materials or may be an alloy. The combination of the plural materials can improve adherence, and reduce deterioration of the electrode characteristics due to, e.g., oxidation.

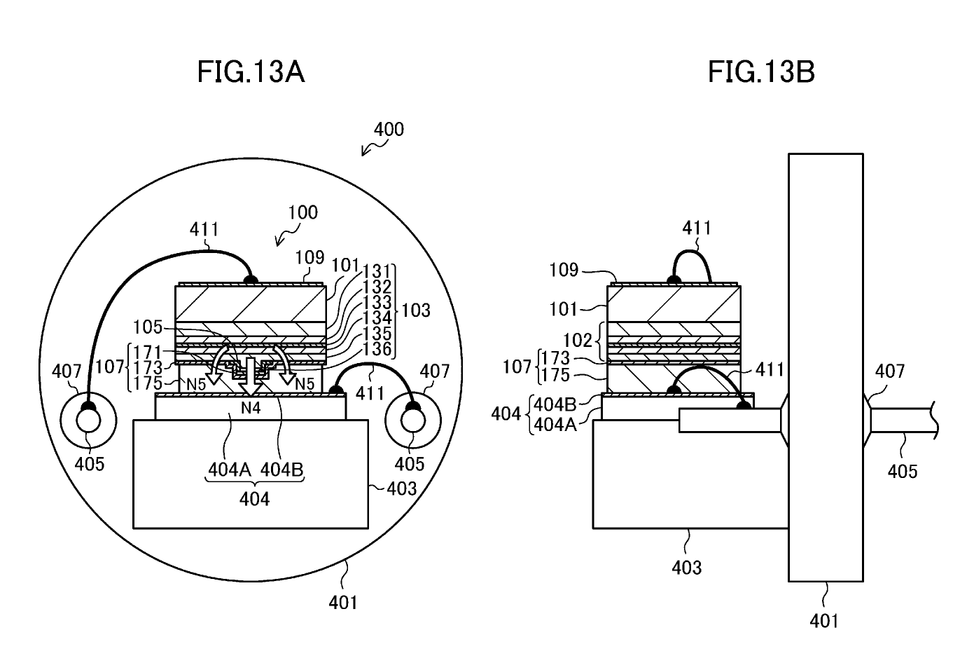

FIG. 7 illustrates the structure in which the n-side electrode 109 is connected to the sub-mount electrode 404B. The p-side electrode 107 may be connected to the sub-mount electrode 404B, as illustrated in FIG. 13. In this case, the heat generated in a portion of the active layer located directly under the ridge is conducted to the p-side electrode 107 formed on the ridge through the path N4. The heat dispersed into the nitride semiconductor layer 103 is efficiently conducted through the path N5 from a portion in which the nitride semiconductor layer 103 and the second electrode 173 are directly connected together to the p-side electrode 107. The heat having been conducted to the p-side electrode 107 is finally conducted to the heat sink 403, and is dissipated. Therefore, even when performing a so-called junction-down mounting in which the p-side electrode is located closer to the heat sink and is mounted on the package, the semiconductor light emitting device of the embodiment can greatly efficiently dissipate the heat, compared with the conventional semiconductor light emitting device. In this case, the third electrode 175 serving as a pad electrode is connected to the heat sink 403 through the sub-mount 404, and therefore, even if the third electrode 175 has a thin thickness, it can efficiently conduct heat to the heat sink 403. Therefore, a sufficient thickness of the third electrode 175 is about several μm.

### First Modification of Embodiment

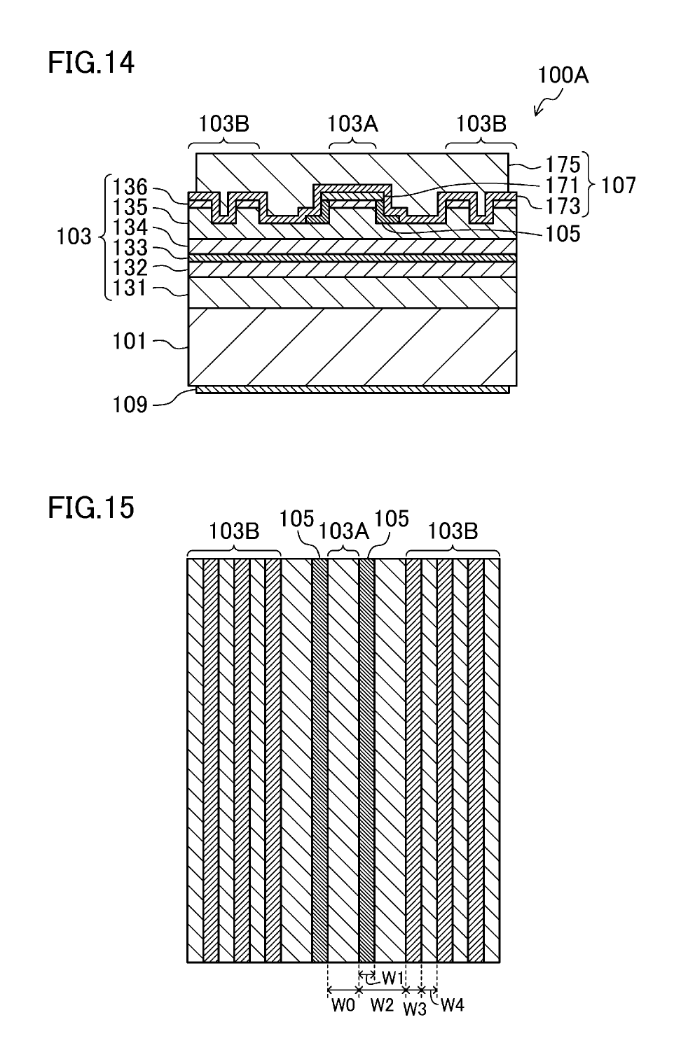

FIG. 14 illustrates a cross-sectional structure of a semiconductor light emitting device 100A according to a first modification of the embodiment. Elements of the structure different from that of the semiconductor light emitting device 100 of the embodiment will be described hereinafter. As illustrated in FIG. 14, the semiconductor light emitting device 100A of the present modification has a nitride semiconductor layer 103 having recessed/raised portions 103B. The recessed/raised portions 103B are formed so as to be spaced apart from the ridge 103A. In the recessed/raised portions 103B, the nitride semiconductor layer 103 and a second electrode 173 serving as an interconnect electrode are directly connected together without an intermediate insulating film 105 interposed therebetween. The recessed/raised portions 103B are provided, whereby the contact area between the second electrode 173 and the nitride semiconductor layer 103 can be increased. Therefore, it is possible to efficiently conduct the heat from the side of the second electrode 173 to the side of the nitride semiconductor layer 103, and the heat from the side of the nitride semiconductor layer 103 to the side of the second electrode 173. Therefore, even when a junction-down mounting is performed, the heat can be efficiently dissipated.

The recessed/raised portions 103B may has any structure as long as a large contact area between the nitride semiconductor layer 103 and the second electrode 173 is secured. For example, stripe-shaped raised portions and stripe-shaped recessed portions extending in parallel to the ridge 103A may be alternately formed, as illustrated in FIG. 15. An interval W2 between the ridge 103A and one of the recessed/raised portions 103B may be larger than a width W1 of a region adjoining the ridge 103A and covered with the insulating film 105, and the width W1 of about 1-10 μm is preferable since high heat dissipation properties can be maintained, and light absorption can be reduced. A width W3 of the raised portion and a width W4 of the recessed portion may be optionally set. If the widths W3 and W4 are about 1 μm, the recessed/raised portions 103B are easily formed by lithography. Smaller widths W3 and W4 obtain an advantage of increasing the contact area. The width W3 of the raised portion and the width W4 of the recessed portion do not have to be the same. All the raised portions or all the recessed portions do not have the same width. The larger the number of the raised portions and the recessed portions is, the larger the contact area between the nitride semiconductor layer 103 and the second electrode 173 is. In the case of a general semiconductor light emitting device in which the width of the edge surface is about 200 μm, about 47 pairs of the raised portions and the recessed portions can be formed if each of the width W3 of the raised portion and the width W4 of the recessed portion is 1 μm.

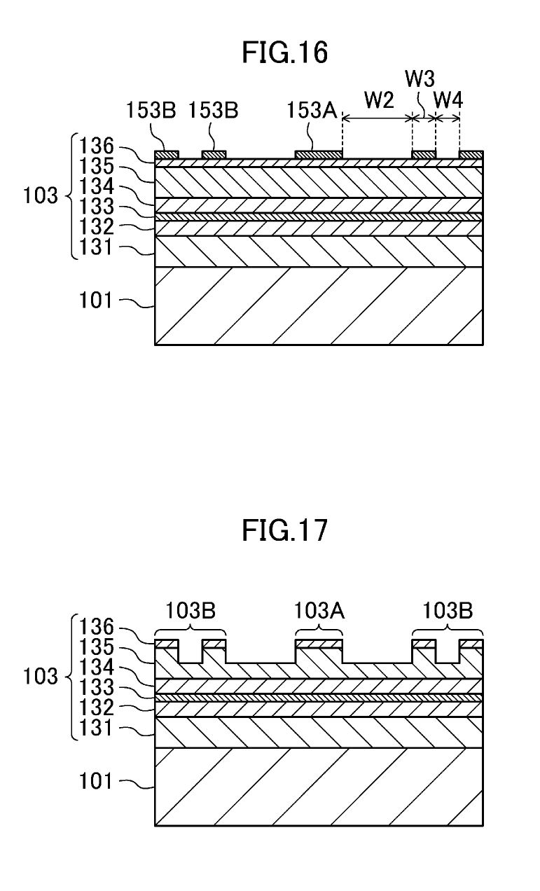

Although the recessed/raised portions 103B may be formed by any methods, the formation process can be simplified if the recessed/raised portions 103B and the ridge 103A are formed by the same process. For example, as illustrated in FIG. 16, a SiO₂ film is formed on the p-type contact layer 136, and then, the film is patterned by photolithography to form a stripe-shaped mask 153A for forming the ridge 103A, and a stripe-shaped mask 153B for forming the recessed/raised portions 103B. Next, as illustrated in FIG. 17, the p-type contact layer 136 and the p-type cladding layer 135 are selectively removed by ICP etching using, e.g., Cl₂ gas to form the recessed/raised portions 103B together with the ridge 103A.

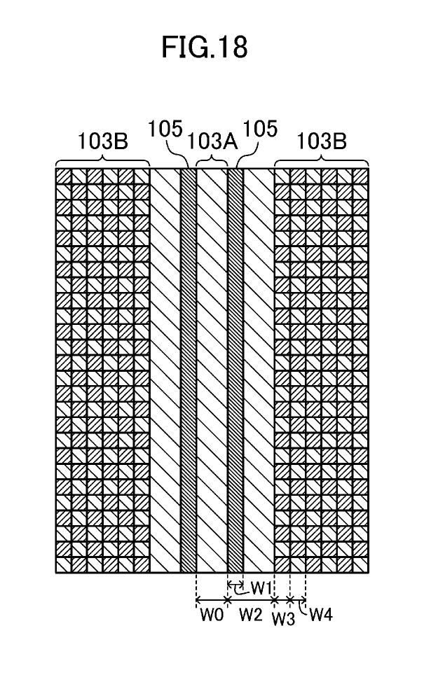

The recessed/raised portions 103B may be arranged in a grid pattern, as illustrated in FIG. 18. Such an arrangement can further increase the contact area between the nitride semiconductor layer 103 and the second electrode 173. For example, if one side of the raised portion is set to be about 1 μm, the contact area between the nitride semiconductor layer 103 and the second electrode 173 can be increased by about two times than the contact area when the recessed portions and the raised portions are set to have a stripe shape of 1 μm.

### Second Modification of Embodiment

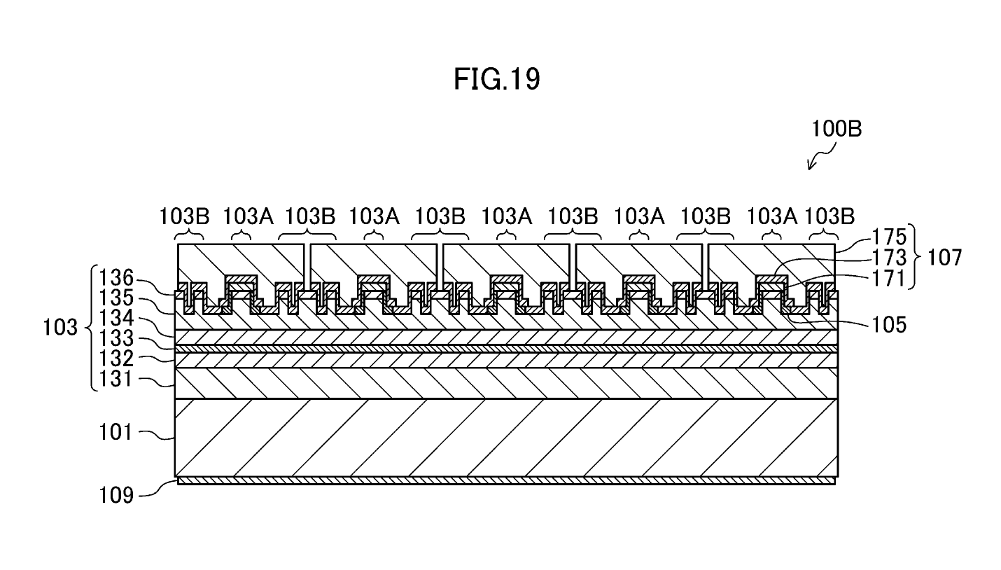

FIG. 19 illustrates a cross-sectional structure of a semiconductor light emitting device 100B according to a second modification of the embodiment. Elements of the structure different from that of the semiconductor light emitting device 100 of the embodiment will be described hereinafter. As illustrated in FIG. 14, the semiconductor light emitting device 100B of the present modification includes a plurality of ridges 103A. The plurality of the ridges 103A are provided, thereby making it possible to increase the value of the maximum light output of the semiconductor light emitting device. In this case, although the amount of heat generation is also increased, the heat can be efficiently dissipated since the semiconductor light emitting device 100B of the present modification has a portion in which a second electrode 173 is directly connected to a p-type cladding layer 135 without an intermediate insulating film 105 interposed therebetween. Since the recessed/raised portions 103B are formed at both sides of the ridge 103A, the contact area between the second electrode 173 and the nitride semiconductor layer 103 can be increased, and therefore, the heat can be further efficiently dissipated. In the present modification, the recessed/raised portions 103B do not have to be necessarily provided.

FIG. 19 illustrates a structure in which the second electrode 173 and the third electrode 175 are divided into several portions, and each of the portions of the second electrode 173 and each of the portions of the third electrode 175 are independently arranged in an associated one of the ridges 103A. Such a structure can independently supply an electric power to each of the ridges 103A, and therefore, the light output can be adjusted in each of the ridges 103A. When an electric power is independently supplied to each of the ridges 103A, it is also possible to perform a junction-up mounting and a junction-down mounting. When a junction-up mounting is performed, each of the portions of the third electrode 175 may be connected to the associated one of the leads and wires. When a junction-down mounting is performed, a sub-mount electrode is patterned to be able to independently supply electric power to each of the portions of the third electrode 175.

If the light output does not have to be adjusted in each of the ridges 103A, each of the second electrode 173 and the third electrode 175 may be continuously formed in all the ridges 103A. In such a structure, the heat generated in a portion of the active layer 133 located directly under each of the ridges 103A can be efficiently dispersed into the semiconductor light emitting device 100B, and the semiconductor light emitting device 100B is allowed to have a uniform temperature. Therefore, a uniform emission strength of light emitted from each of the ridge 103A can be also obtained.

In the first and second modifications, the second electrode 173 and the p-type contact layer 136 are in contact with each other on the raised portions. However, if the second electrode 173 is formed after the first electrode 171 and the p-type contact layer 136 are sintered, an ohmic contact is not formed between the second electrode 173 and the p-type contact layer 136, and current hardly flows from the second electrode 173 to the p-type contact layer 136.

### Third Modification of Embodiment

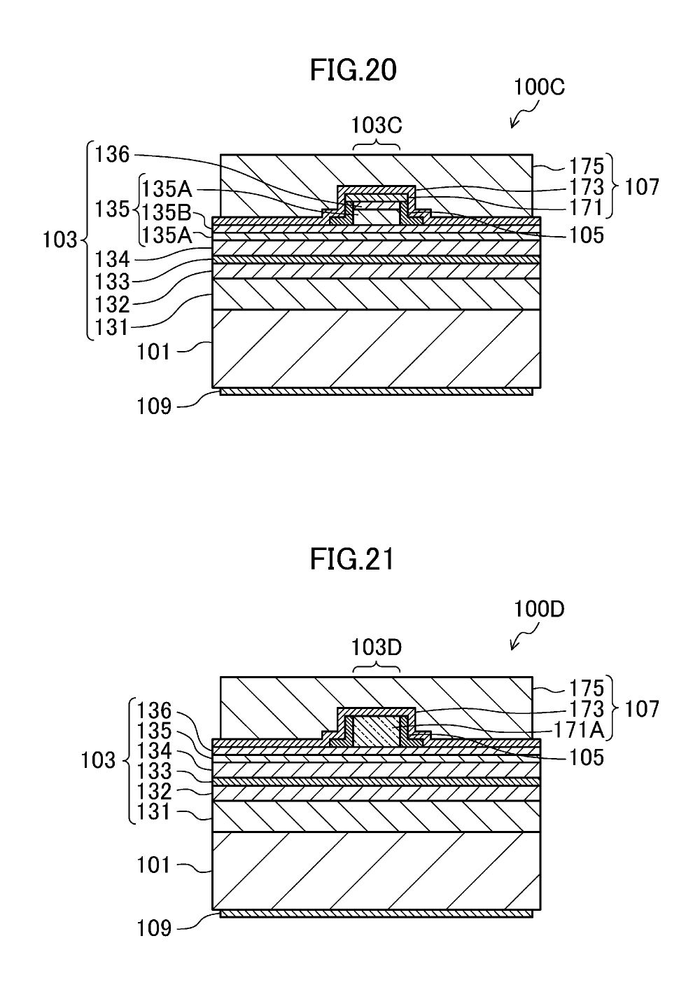

The embodiment and the previous modifications illustrate the example in which one p-type cladding layer is formed. The p-type cladding layer may have a laminated structure made of a plurality of layers having different compositions from each other and different materials from each other. FIG. 20 illustrates a cross-sectional structure of a semiconductor light emitting device 100C according to a third modification of the embodiment. Elements of the structure different from that of the semiconductor light emitting device 100 of the embodiment will be described hereinafter. As illustrated in FIG. 20, the semiconductor light emitting device 100C of the present modification has the p-type cladding layer 135 having a laminated structure formed by a first layer 135A and a second layer 135B having different compositions from each other. For example, the second layer 135B is made of an AlGaN layer in which an Al composition ratio is larger than that in the first layer 135A, thereby causing a difference between the etching rate of the first layer 135A and the etching rate of the second layer 135B. As a result, the second layer 135B can be an etching stop layer used when a ridge 103C is formed. The second layer 135B is allowed to serve as an etching stop layer, thereby making it possible to precisely control the height of the ridge 103C. It is also possible to reduce penetration of the layers due to etching.

When the second layer 135B is formed to include p-type impurities at a low concentration, current leakage from the interconnect electrode 173 can be further reduced.

FIG. 20 illustrates an example in which the second layer is sandwiched between the first layers. A structure in which the first layer is provided under the second layer, and a third layer having a different composition from that of the first layer is provided over the second layer may be used.

In the present modification, the recessed/raised portions may be provided as well as the first modification. Also, a plurality of ridges may be provided as well as the second modification.

### Fourth Modification of Embodiment

The embodiment and the previous modifications illustrate the example in which the ridge is integrally formed with the p-type cladding layer. The ridge may be formed by a layer having a different composition from the p-type cladding layer or a different material from the p-type cladding layer. FIG. 21 illustrates a cross-sectional structure of a semiconductor light emitting device 100D according to a fourth modification of the embodiment. Elements of the structure different from that of the semiconductor light emitting device 100 of the embodiment will be described hereinafter.

As illustrated in FIG. 21, in the semiconductor light emitting device 100D of the present modification, a ridge 103D is formed by a first electrode 171A that is transparent for an emission wavelength of light. Even if the ridge 103D is formed by the first electrode 171A that is transparent for an emission wavelength of light, light can be confined as well as the case of having the ridge 103A integrally formed with the p-type cladding layer 135. The first electrode 171A is formed on only a part of the p-type cladding layer 135, and therefore, current can be confined, too. The transparent first electrode 171A may be made of, e.g., indium tin oxide (ITO) having a thickness of, e.g., about 300 nm.

Such a structure can reduce the thickness of the p-type cladding layer 135. The thickness of the p-type cladding layer 135 can be, e.g., 0.1-0.2 μm. It has been generally known that an InAlGaN-based nitride semiconductor of p-type has a high electrical resistance, and the thickness of the p-type cladding layer 135 is reduced, thereby making it possible to reduce a series resistance and an operating voltage. Since the power supplied to the device can be reduced by the simple process, it is useful to reduce the amount of heat generation. The p-type contact layer 136 and the second electrode 173 are in contact with each other, whereby the heat can be efficiently conducted from the side of the second electrode 173 to the side of the nitride semiconductor layer 103, and from the side of the nitride semiconductor layer 103 to the side of the second electrode 173. Therefore, even when a junction-down mounting or a junction-up mounting is performed, the heat can be efficiently dissipated.

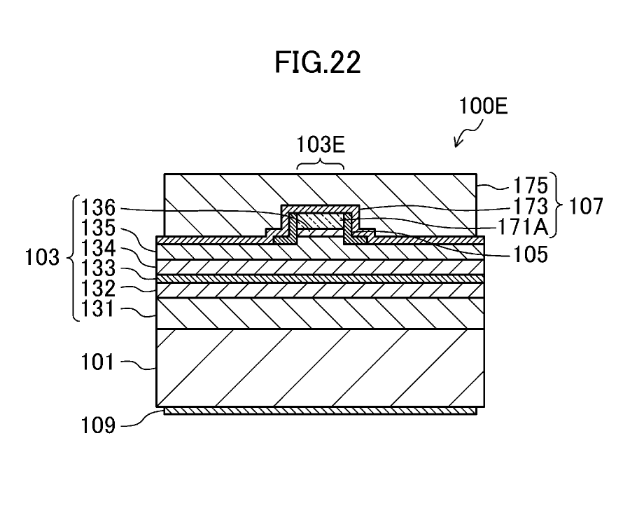

As illustrated in FIG. 22, a semiconductor light emitting device 100E in which the p-type contact layer 136 except a portion included in the ridge 103E is removed may be used. In this case, for example, the p-type contact layer 136 and the first electrode 171A are formed on the p-type cladding layer 135, and then, they are selectively etched until a portion of the p-type cladding layer 135 is exposed, thereby forming the ridge 103E including the first electrode 171A.

The p-type contact layer 136 expect a portion thereof located directly under the ridge 103E is removed by etching, whereby a low-nitrogen layer can be formed. The formation of the low-nitrogen layer further reduce current leakage from the second electrode 173 serving as an interconnect electrode. The etching for forming the ridge 103E may be ICP etching using, e.g., Cl₂ gas.

FIG. 22 illustrates an example in which the upper part of the p-type cladding layer 135 is etched together with the p-type contact layer 136. Only the p-type contact layer 136 may be removed.

In the present modification, the recessed/raised portions may be provided as well as the first modification. Also, a plurality of ridges may be provided as well as the second modification.

The semiconductor light emitting device of the present disclosure can significantly improve heat dissipation without reducing luminous efficiency. In particular, the semiconductor light emitting device and the light emitting apparatus of the present disclosure is useful as, e.g., a semiconductor light emitting device using a nitride semiconductor and a light emitting apparatus.

What is claimed is:

1. A semiconductor light emitting device, comprising:
a nitride semiconductor layer including a first cladding layer, a light emitting layer, and a second cladding layer which are sequentially provided on a substrate, the second cladding layer including at least one ridge;
an insulating film provided on a portion of the second cladding layer including the at least one ridge;
a first electrode provided on the at least one ridge; and
a second electrode provided to contact the first electrode, the insulating film, and a portion of the second cladding layer exposed from the insulating film,
wherein
the insulating film is provided on a side surface of the at least one ridge and a region adjoining the at least one ridge.

2. The semiconductor light emitting device of claim 1, wherein
a width of a portion of the insulating film provided on the region adjoining the at least one ridge is 1 μm or more and 10 μm or less.

3. The semiconductor light emitting device of claim 1, wherein
a width of a portion of the insulating film provided on the region adjoining the at least one ridge is 1 μm or more and 2 μm or less.

4. The semiconductor light emitting device of claim 1, wherein
a nitrogen density of a portion of the second cladding layer around an interface with the second electrode is smaller than a nitrogen density of an inside portion of the second cladding layer.

5. The semiconductor light emitting device of claim 1, wherein
the second electrode is made of a material having a work function smaller than that of the first electrode.

6. The semiconductor light emitting device of claim 1, wherein
the second cladding layer has a recessed/raised structure provided in a portion which is not covered with the insulating film.

7. The semiconductor light emitting device of claim 6, wherein
the recessed/raised structure is provided in a stripe pattern extending in parallel to the at least one ridge.

8. The semiconductor light emitting device of claim 6, wherein
the recessed/raised structure is provided in a grid pattern.

9. The semiconductor light emitting device of claim 1, wherein
the at least one ridge includes a plurality of ridges, and
the second cladding layer has the plurality of ridges.

10. The semiconductor light emitting device of claim 1, wherein
the second cladding layer includes a plurality of layers having different compositions from each other or different materials from each other.

11. A semiconductor light emitting device, comprising:
a nitride semiconductor layer including a first cladding layer, a light emitting layer, and a second cladding layer which are sequentially provided on a substrate;
at least one ridge provided on the second cladding layer and including a first electrode made of a material which is transparent for an emission wavelength of light;
an insulating film provided on a portion of the second cladding layer; and
a second electrode provided to contact the at least one ridge, the insulating film, and a portion of the second cladding layer exposed from the insulating film,
wherein
the insulating film is provided on a side surface of the at least one ridge and a region adjoining the at least one ridge.

12. A semiconductor light emitting apparatus, comprising:
a heat sink; and
the semiconductor light emitting device of claim 1 mounted on the heat sink, wherein
the substrate of the semiconductor light emitting device faces the heat sink.

13. A semiconductor light emitting apparatus, comprising:
a heat sink; and
the semiconductor light emitting device of claim 1 mounted on the heat sink, wherein
the second cladding layer of the semiconductor light emitting device faces the heat sink.
